(19) United States
(12) Patent Application Publication
(10) Pub. No.: US 2018/0342678 A1
(43) Pub. Date: Nov. 29, 2018

(54) OLED DEVICE MANUFACTURE METHOD AND OLED DEVICE

(71) Applicant: WUHAN CHINA STAR OPTOELECTRONICS TECHNOLOGY CO., LTD., Wuhan, Hubei (CN)

(72) Inventor: Chao Xu, Wuhan, Hubei (CN)

(73) Assignee: WUHAN CHINA STAR OPTOELECTRONICS TECHNOLOGY CO., LTD., Wuhan, Hubei (CN)

(21) Appl. No.: 15/329,490

(22) PCT Filed: Dec. 29, 2016
(86) PCT No.: PCT/CN2016/112944

§ 371 Date: Jan. 26, 2017

(30) Foreign Application Priority Data
Nov. 28, 2016 (CN) 201611069709.2

(51) Int. Cl. H01L 51/00; H01L 27/32; H01L 51/52; H01L 51/50; H01L 51/56; B32B 37/12

(52) U.S. Cl. CPC H01L 51/0024; B32B 2457/206; H01L 51/0097; H01L 51/5206; H01L 51/5234; H01L 51/5012; H01L 51/5056; H01L 51/5072; H01L 51/5088; H01L 51/5253; H01L 51/56; B32B 37/1284; H01L 2227/323; H01L 2251/5338; H01L 2251/308; H01L 27/3251

(57) ABSTRACT

An OLED (Organic Light-Emitting Diode) device manufacture method and an OLED device are provided. The method includes steps of sequentially forming a TFT (Thin Film Transistor) array layer, a negative electrode layer, an electron transport layer, a light-emitting layer, and a hole transport layer on a first substrate; forming a first electron gluing layer on the hole transport layer; sequentially forming a positive electrode layer and a hole injection layer on a second substrate; forming a second electron gluing layer on the hole injection layer; and adhering and connecting the first electron gluing layer and the second electron gluing layer.

### TECHNICAL FIELD OF THE DISCLOSURE

The present invention relates to a display technology, and more particularly, to an OLED (Organic Light-Emitting Diode) device manufacture method and an OLED device.

### BACKGROUND OF THE DISCLOSURE

OLED displays have many advantages such as high brightness, fast response, low energy consumption, and flexible. The OLED displays are widely regarded as a focus of next-generation display technology. Compared to TFT-LCD, the advantage of OLED is that it has an ability to produce a large-scale, super thin, flexible, and transparent display device.

The problems of transparent electrodes are required to be solved in manufacturing a transparent OLED display. The material of transparent electrodes requires not only high conductivity but also high transmittance. The material of transparent electrodes currently in use is primarily ITO. Since organic thin film is much thinner in evaporation and ITO is usually manufactured by a sputtering device with physical vapor deposition, an organic light-emitting layer may be damaged if the power of sputtering is too high and film formation may take much time and the production efficiency is reduced if the power of sputtering is too low.

Therefore, the existing skills have drawbacks and need to be improved.

### SUMMARY OF THE DISCLOSURE

The objective of the present invention is to provide an OLED (Organic Light-Emitting Diode) device manufacture method and an OLED device.

To solve above technical problems, the technical schemes provided in the present invention are described below.

The present invention provides an OLED device manufacture method, comprising steps of: sequentially forming a TFT (Thin Film Transistor) array layer, a negative electrode layer, an electron transport layer, a light-emitting layer, and a hole transport layer on a first substrate; forming a first electron gluing layer on the hole transport layer; sequentially forming a positive electrode layer and a hole injection layer on a second substrate; forming a second electron gluing layer on the hole injection layer; and adhering and connecting the first electron gluing layer and the second electron gluing layer.

In the OLED device manufacture method of the present invention, the step of adhering and connecting the first electron gluing layer and the second electron gluing layer comprises: aligning and pressing the first substrate and the second substrate together under a vacuum condition to make the first electron gluing layer and the second electron gluing layer attached and adhered to each other.

In the OLED device manufacture method of the present invention, the step of sequentially forming the TFT array layer, the negative electrode layer, the electron transport layer, the light-emitting layer, and the hole transport layer on the first substrate comprises: disposing the TFT array layer on the first substrate; disposing the negative electrode layer on the TFT array layer; disposing the electron transport layer on the negative electrode layer; disposing the light-emitting layer on the electron transport layer; and disposing the hole transport layer on the light-emitting layer.

In the OLED device manufacture method of the present invention, the step of sequentially forming the positive electrode layer and the hole injection layer on the second substrate comprises: disposing a barrier layer on the second substrate; disposing the positive electrode layer on the barrier layer; and disposing the hole injection layer on the positive electrode layer.

In the OLED device manufacture method of the present invention, the first electron gluing layer and the second gluing layer are implemented by sorbitol.

In the OLED device manufacture method of the present invention, the step of forming the first electron gluing layer on the hole transport layer comprises: forming the first electron gluing layer on the hole transport layer by evaporation or spin coating.

In the OLED device manufacture method of the present invention, the step of forming the second electron gluing layer on the hole injection layer comprises: forming the second electron gluing layer on the hole injection layer by evaporation or spin coating.

The present invention further provides an OLED device manufacture method, comprising steps of: sequentially forming a TFT (Thin Film Transistor) array layer, a negative electrode layer, an electron transport layer, a light-emitting layer, and a hole transport layer on a first substrate; forming a first electron gluing layer on the hole transport layer; sequentially forming a positive electrode layer and a hole injection layer on a second substrate; forming a second electron gluing layer on the hole injection layer; and aligning and pressing the first substrate and the second substrate together under a vacuum condition to make the first electron gluing layer and the second electron gluing layer attached and adhered to each other; wherein the first electron gluing layer and the second gluing layer are implemented by sorbitol.

The present invention further provides an OLED device, comprising: a first substrate, and a TFT (Thin Film Transistor) array layer, a negative electrode layer, an electron transport layer, a light-emitting layer, a hole transport layer, and a first electron gluing layer sequentially formed on the first substrate; and a second substrate, and a barrier layer, a positive electrode layer, a hole injection layer, and a second electron gluing layer sequentially formed on the second substrate; wherein the first electron gluing layer and the second electron gluing layer are attached and adhered to each other.

In the OLED device of the present invention, the first electron gluing layer and the second gluing layer are implemented by sorbitol.

In the OLED device of the present invention, the positive electrode layer and the negative electrode layer are implemented by ITO (Indium Tin Oxide).

As can be seen from above, in the embodiment of the present invention, a TFT array layer, a negative electrode layer, an electron transport layer, a light-emitting layer, and a hole transport layer are sequentially formed on a first substrate. A first electron gluing layer is formed on the hole transport layer. A positive electrode layer and a hole injection layer are sequentially formed on a second substrate. A second electron gluing layer is formed on the hole injection layer. The first electron gluing layer and the second electron gluing layer are adhered and connected together. Therefore, the manufacture of an OLED device is carried out. In the present embodiment, the manufacture of the OLED device is divided into two parts, and then the electron gluing layers are used to adhere the two parts. The beneficial effect is that the production is speeded up. Also, during the manufacture, the positive electrode layer and the light-emitting layer are manufactured separately. In this way, this can avoid a damage of the light-emitting layer caused by sputtering in forming the positive electrode layer using physical vapor deposition. Therefore, the yield of the product is improved.

### BRIEF DESCRIPTION OF THE DRAWINGS

FIG. 1 is a flow chart of an OLED (Organic Light-Emitting Diode) device manufacturing method in accordance with a preferred embodiment of the present invention.

FIG. 2 is a schematic diagram showing a partial structure of an OLED device of an embodiment shown in FIG. 1 in accordance with the present invention.

FIG. 3 is a schematic diagram showing another partial structure of an OLED device of an embodiment shown in FIG. 1 in accordance with the present invention.

FIG. 4 is a structural diagram showing an OLED device in accordance with a preferred embodiment of the present invention.

### DETAILED DESCRIPTION OF THE DISCLOSURE

The following descriptions for the respective embodiments are specific embodiments capable of being implemented for illustrations of the present invention with referring to appending figures. In descripting the present invention, spatially relative terms such as “upper”, “lower”, “front”, “back”, “left”, “right”, “inner”, “outer”, “lateral”, and the like, may be used herein for ease of description as illustrated in the figures. Therefore, the spatially relative terms used herein are intended to illustrate the present invention for ease of understanding, but are not intended to limit the present invention.

In the appending drawings, units with similar structures are indicated by the same reference numbers.

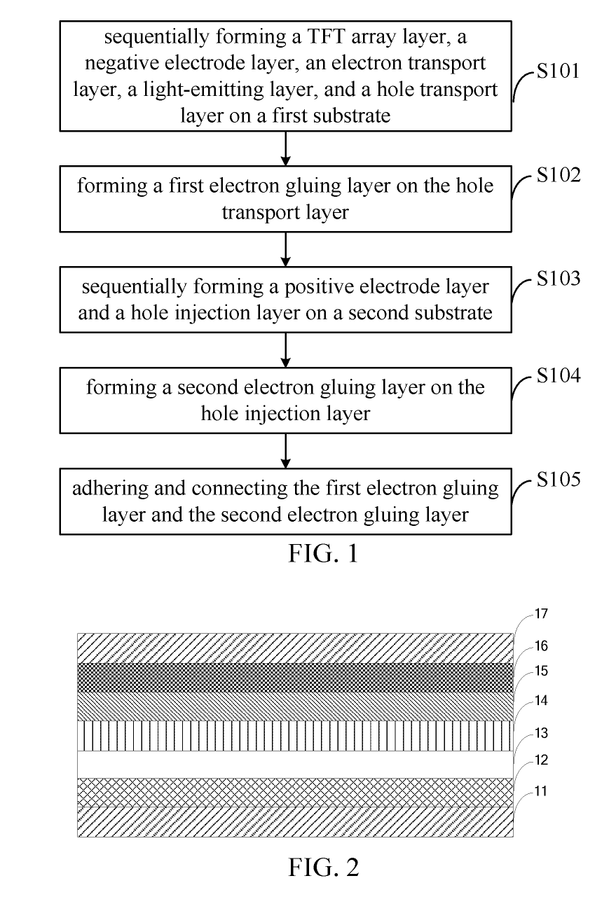

Referring to FIG. 1, the OLED (Organic Light-Emitting Diode) device manufacturing method includes the following steps.

Step S101: sequentially forming a TFT (Thin Film Transistor) array layer, a negative electrode layer, an electron transport layer, a light-emitting layer, and a hole transport layer on a first substrate.

Step S102: forming a first electron gluing layer on the hole transport layer.

Step S103: sequentially forming a positive electrode layer and a hole injection layer on a second substrate.

Step S104: forming a second electron gluing layer on the hole injection layer.

Step S105: adhering and connecting the first electron gluing layer and the second electron gluing layer.

The respective steps of the OLED device manufacturing method are detailedly described below. In the afore-described steps, Step S102 is executed after Step S101 and Step S104 is executed after Step S103. However, Step S101 and Step S103 can be executed simultaneously and can also be executed in an arbitrary order.

Referring to FIG. 2, Step S101 includes the following sub-steps.

Step S1011: disposing the TFT array layer on the first substrate. In this step, the first substrate 11 can be implemented by a flexible substrate. The TFT array layer 12 includes a plurality of thin film transistors.

Step S1012: disposing the negative electrode layer on the TFT array layer. In this step, the negative electrode layer 13 is formed on the TFT array layer 12 using physical vapor deposition, in which the negative electrode layer 13 adopts a transparent material such as n-type oxide semiconductors, for example, ITO (Indium Tin Oxide).

Step S1013: disposing the electron transport layer 14 on the negative electrode layer 13. In this step, evaporation and spin coating can be adopted for forming the electron transport layer 14 on the negative electrode layer 13.

Step S1014: disposing the light-emitting layer on the electron transport layer. In this step, evaporation and spin coating can be adopted for forming the light-emitting layer 15 on the electron transport layer 14. The light-emitting layer 15 is an organic light-emitting layer.

Step S1015: disposing the hole transport layer on the light-emitting layer. In this step, evaporation and spin coating can be adopted for forming the hole transport layer 16 on the light-emitting layer 15.

In Step S102, evaporation and spin coating can be used to form the first electron gluing layer 17 on the hole transport layer 16. The first electron gluing layer 17 is highly transparent and has a high carrier mobility. The first electron gluing layer 17 can be implemented by sorbitol.

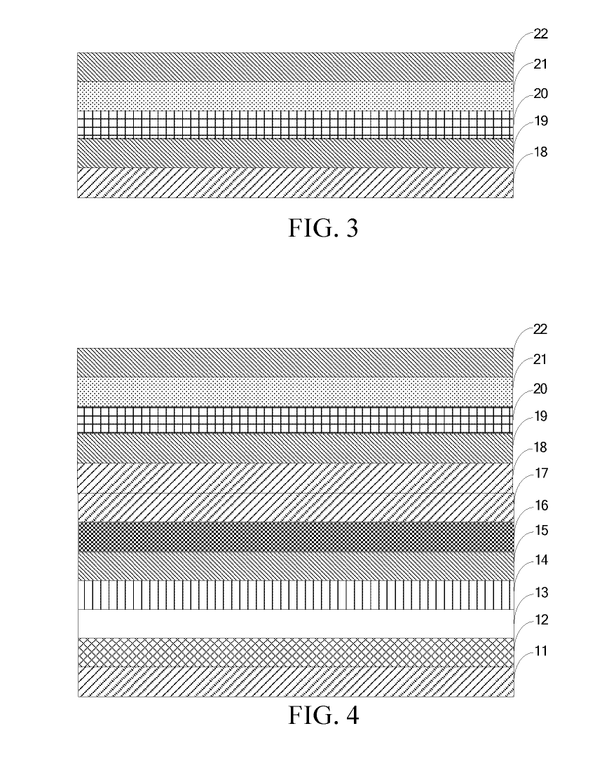

Referring to FIG. 3, Step S103 includes the following sub-steps.

Step S1031: disposing a barrier layer on the second substrate. In this step, the second substrate 22 can be a flexible substrate. The barrier layer 21 is formed by depositing an inorganic material having a better performance in water vapor and oxygen separation. The inorganic material is implemented by SiNₓ and SiO₂, for example.

Step S1032: disposing the positive electrode layer on the barrier layer. In this step, the positive electrode layer 20 is formed on the barrier layer 21 using physical vapor deposition, in which the positive electrode layer 20 adopts a transparent material such as n-type oxide semiconductors, for example, ITO (Indium Tin Oxide).

Step S1033: disposing the hole injection layer on the positive electrode layer. In this step, evaporation and spin coating can be adopted for forming the hole injection layer 19.

In Step S104, evaporation and spin coating can be utilized to form the second electron gluing layer on the hole injection layer. The second electron gluing layer 18 is highly transparent and has a high carrier mobility. The second electron gluing layer 18 can be implemented by sorbitol.

In Step S105, the first substrate 11 and the second substrate 18 are aligned and are pressed together under vacuum conditions such that the first electron gluing layer 17 and the second electron gluing layer 18 are attached and adhered to each other. After that, they are baked for one to five minutes at a temperature higher than the melting point of the first electron gluing layer 17 and the second electron gluing layer 18. After they cool, the manufacture of the OLED device is finished.

As can be seen from above, in the embodiment of the present invention, a TFT array layer, a negative electrode layer, an electron transport layer, a light-emitting layer, and a hole transport layer are sequentially formed on a first substrate. A first electron gluing layer is formed on the hole transport layer. A positive electrode layer and a hole injection layer are sequentially formed on a second substrate. A second electron gluing layer is formed on the hole injection layer. The first electron gluing layer and the second electron gluing layer are adhered and connected together. Therefore, the manufacture of an OLED device is carried out. In the present embodiment, the manufacture of the OLED device is divided into two parts, and then the electron gluing layers are used to adhere the two parts. The beneficial effect is that the production is speeded up. Also, during the manufacture, the positive electrode layer and the light-emitting layer are manufactured separately. In this way, this can avoid a damage of the light-emitting layer caused by sputtering in forming the positive electrode layer using physical vapor deposition. Therefore, the yield of the product is improved.

FIG. 4 is a structural diagram showing an OLED device in accordance with a preferred embodiment of the present invention. The OLED device includes a first substrate 11, an TFT array layer 12, a negative electrode layer 13, an electron transport layer 14, a light-emitting layer 15, a hole transport layer 16, a first electron gluing layer 17, and a second substrate 22.

The TFT array layer 12, the negative electrode layer 13, the electron transport layer 14, the light-emitting layer 15, the hole transport layer 16, and the first electron gluing layer 17 are sequentially formed on the first substrate 11.

Specifically, the TFT array layer 12 is deposited onto the first substrate 11. The TFT array layer is a pixel electrode layer. The negative electrode layer 13 is formed on the TFT array layer 12 using physical vapor deposition. The electron transport layer 14 is formed on the negative electrode layer 13 by evaporation or spin coating. The light-emitting layer 15 is an organic light-emitting layer, which is formed on the electron transport layer 16 by evaporation or spin coating. The hole transporting layer 16 is formed on the light-emitting layer 15 by evaporation or spin coating.

A barrier layer 21, a positive electrode layer 20, a hole injection layer 19, and a second electron gluing layer 18 are sequentially formed on the second substrate 22.

The first electron gluing layer 17 and the second electron gluing layer 18 are attached and adhered to each other. The first electron gluing layer 17 and the second gluing layer 18 are implemented by sorbitol. The positive electrode layer 20 and the negative electrode layer 13 are implemented by ITO.

As can be seen from above, in the embodiment of the present invention, the positive electrode layer and the light-emitting layer are manufactured separately. In this way, this can avoid a damage of the light-emitting layer caused by sputtering in forming the positive electrode layer using physical vapor deposition. Therefore, the yield of the product is improved.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. An OLED (Organic Light-Emitting Diode) device manufacture method, comprising steps of:
sequentially forming a TFT (Thin Film Transistor) array layer, a negative electrode layer, an electron transport layer, a light-emitting layer, and a hole transport layer on a first substrate;
forming a first electron gluing layer on the hole transport layer;
sequentially forming a positive electrode layer and a hole injection layer on a second substrate;
forming a second electron gluing layer on the hole injection layer; and
adhering and connecting the first electron gluing layer and the second electron gluing layer.

2. The OLED device manufacture method according to claim 1, wherein the step of adhering and connecting the first electron gluing layer and the second electron gluing layer comprises:
aligning and pressing the first substrate and the second substrate together under a vacuum condition to make the first electron gluing layer and the second electron gluing layer attached and adhered to each other.

3. The OLED device manufacture method according to claim 1, wherein the step of sequentially forming the TFT array layer, the negative electrode layer, the electron transport layer, the light-emitting layer, and the hole transport layer on the first substrate comprises:
disposing the TFT array layer on the first substrate;
disposing the negative electrode layer on the TFT array layer;
disposing the electron transport layer on the negative electrode layer;
disposing the light-emitting layer on the electron transport layer; and
disposing the hole transport layer on the light-emitting layer.

4. The OLED device manufacture method according to claim 1, wherein the step of sequentially forming the positive electrode layer and the hole injection layer on the second substrate comprises:
disposing a barrier layer on the second substrate;
disposing the positive electrode layer on the barrier layer; and
disposing the hole injection layer on the positive electrode layer.

5. The OLED device manufacture method according to claim 1, wherein the first electron gluing layer and the second gluing layer are implemented by sorbitol.

6. The OLED device manufacture method according to claim 1, wherein the step of forming the first electron gluing layer on the hole transport layer comprises:
forming the first electron gluing layer on the hole transport layer by evaporation or spin coating.

7. The OLED device manufacture method according to claim 1, wherein the step of forming the second electron gluing layer on the hole injection layer comprises:
forming the second electron gluing layer on the hole injection layer by evaporation or spin coating.

8. An OLED (Organic Light-Emitting Diode) device manufacture method, comprising steps of:
sequentially forming a TFT (Thin Film Transistor) array layer, a negative electrode layer, an electron transport layer, a light-emitting layer, and a hole transport layer on a first substrate;
forming a first electron gluing layer on the hole transport layer;
sequentially forming a positive electrode layer and a hole injection layer on a second substrate;
forming a second electron gluing layer on the hole injection layer; and
aligning and pressing the first substrate and the second substrate together under a vacuum condition to make the first electron gluing layer and the second electron gluing layer attached and adhered to each other;
wherein the first electron gluing layer and the second gluing layer are implemented by sorbitol.

9. An OLED (Organic Light-Emitting Diode) device, comprising:
a first substrate, and a TFT (Thin Film Transistor) array layer, a negative electrode layer, an electron transport layer, a light-emitting layer, a hole transport layer, and a first electron gluing layer sequentially formed on the first substrate; and
a second substrate, and a barrier layer, a positive electrode layer, a hole injection layer, and a second electron gluing layer sequentially formed on the second substrate;
wherein the first electron gluing layer and the second electron gluing layer are attached and adhered to each other.

10. The OLED device according to claim 9, wherein the first electron gluing layer and the second gluing layer are implemented by sorbitol.

11. The OLED device according to claim 8, wherein the positive electrode layer and the negative electrode layer are implemented by ITO (Indium Tin Oxide).
